(19) United States
(12) Patent Application Publication
(10) Pub. No.: US 2025/0329632 A1
(43) Pub. Date: Oct. 23, 2025

(54) SEMICONDUCTOR DEVICE AND METHOD FOR MANUFACTURING THE SAME

(71) Applicant: SAMSUNG ELECTRONICS CO., LTD., Suwon-si (KR)

(72) Inventors: Jinwoo Lee, Suwon-si (KR); Sutae Kim, Suwon-si (KR); Yubo Qian, Suwon-si (KR)

(21) Appl. No.: 19/059,054

(22) Filed: Feb. 20, 2025

(30) Foreign Application Priority Data
Apr. 18, 2024 (KR) 10-2024-0052101

(51) Int. Cl. H01L 23/522; H01L 23/528; H10D 30/00; H10D 30/01; H10D 62/10; H10D 62/13; H10D 64/23; H10D 84/01; H10D 84/83

(52) U.S. Cl. CPC H01L 23/5226; H01L 23/528; H01L 23/5283; H01L 23/5286; H10D 30/0191; H10D 30/503; H10D 30/506; H10D 62/121; H10D 62/151; H10D 64/256; H10D 84/0149; H10D 84/8312; H10D 84/83125; H10D 84/832

(57) ABSTRACT

Provided is a semiconductor device including a power distribution network layer on a lower surface of a substrate, a gate electrode on the substrate, a first source/drain pattern and a second source/drain pattern on the substrate, the first and second source/drain patterns each including a first pattern and a second pattern spaced apart from each other with the gate electrode therebetween, a through via structure penetrating the substrate and extending along a direction perpendicular to an upper surface of the substrate, the through via structure connecting the power distribution network layer and the first pattern of the first source/drain pattern, and a rear surface power via extending from below the second pattern of the first source/drain pattern to below the second pattern of the second source/drain pattern.

### CROSS-REFERENCE TO RELATED APPLICATION(S)

This U.S. non-provisional patent application claims priority under 35 U.S.C. § 119 to Korean Patent Application No. 10-2024-0052101, filed on Apr. 18, 2024, the entire contents of which are hereby incorporated by reference.

### BACKGROUND

A semiconductor device includes an integrated circuit composed of metal-oxide-semiconductor field effect transistors (MOSFETs). As a size and a design rule of the semiconductor device are gradually reduced, scaling down the metal-oxide-semiconductor field effect transistors is gradually being accelerated. As the metal-oxide-semiconductor field effect transistors are scaled down, operation characteristics of the semiconductor device may be deteriorated. Accordingly, research on various methods for forming a semiconductor device having improved performance while overcoming limitation caused by high integration of the semiconductor device is being conducted.

### SUMMARY

The present disclosure provides semiconductor devices exhibiting improved power consumption.

The present disclosure also provides semiconductor devices that may be more easily designed.

Technical goals of the present disclosure are not limited to those mentioned above, and other technical goals and advantages that are not mentioned may be clearly understood from description below by those skilled in the art.

Some implementations of the present disclosure provide a semiconductor device including a power distribution network layer on a lower surface of a substrate, a gate electrode on the substrate, a first source/drain pattern and a second source/drain pattern on the substrate, the first and second source/drain patterns each including a first pattern and a second pattern spaced apart from each other with the gate electrode therebetween, a through via structure penetrating the substrate and extending along a direction perpendicular to an upper surface of the substrate, the through via structure connecting the power distribution network layer and the first pattern of the first source/drain pattern, and a rear surface power via extending from below the second pattern of the first source/drain pattern to below the second pattern of the second source/drain pattern.

In some implementations of the present disclosure, a semiconductor device includes a power distribution network layer on a lower surface of a substrate, a gate electrode on the substrate, a first source/drain pattern and a second source/drain pattern on the substrate, the first and second source/drain patterns each including a first pattern and a second pattern spaced apart from each other with the gate electrode therebetween, a through via structure penetrating the substrate and extending along a direction perpendicular to an upper surface of the substrate, the through via structure connecting the power distribution network layer and the first pattern of the first source/drain pattern, a rear surface power rail extending, below the second source/drain pattern, in one direction parallel to the upper surface of the substrate, and a rear surface power via extending from below the second pattern of the first source/drain pattern to an upper surface of the rear surface power rail.

In some implementations of the present disclosure, a semiconductor device includes a power distribution network layer on a lower surface of a substrate, a gate electrode on the substrate, a first source/drain pattern and a second source/drain pattern on the substrate, the first and second source/drain patterns each including a first pattern and a second pattern spaced apart from each other with the gate electrode therebetween, a first channel pattern between the first pattern and the second pattern of the first source/drain pattern, a through via structure penetrating the substrate and extending along a direction perpendicular to an upper surface of the substrate, the through via structure connecting the power distribution network layer and the first pattern of the first source/drain pattern, an active contact on the first pattern of the second source/drain pattern, a rear surface power rail extending, below the second source/drain pattern, in one direction parallel to the upper surface of the substrate, and a rear surface power via extending from below the second pattern of the first source/drain pattern to an upper surface of the rear surface power rail.

### BRIEF DESCRIPTION OF THE DRAWINGS

The accompanying drawings are included to provide a further understanding of the disclosure, and are incorporated in and constitute a part of this specification. The drawings illustrate implementations according to the present disclosure and, together with the description, serve to explain principles thereof. In the drawings:

FIG. 1 is a plan view illustrating an example of a semiconductor device;

FIG. 2A is a block diagram illustrating an example of a semiconductor device including a power gating circuit;

FIG. 2B is a partially enlarged view of some configurations of FIG. 1;

FIGS. 3A to 3D are cross-sectional views respectively taken along lines A-A′, B-B′, C-C′, and D-D′ of FIG. 1;

FIG. 4 is a plan view illustrating an example of a semiconductor device;

FIGS. 5A to 5C are cross-sectional views respectively taken along lines B-B′, C-C′, and D-D′ of FIG. 4; and

FIGS. 6A to 10D are diagrams illustrating an example of a method for manufacturing a semiconductor device.

### DETAILED DESCRIPTION

Hereinafter, examples according to the present disclosure will be described in more detail with reference to the accompanying drawings.

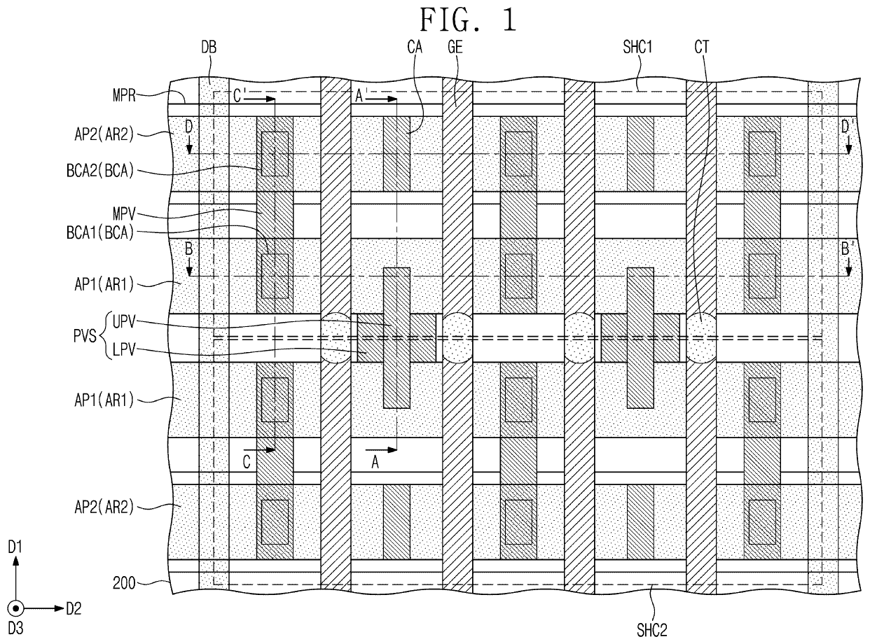

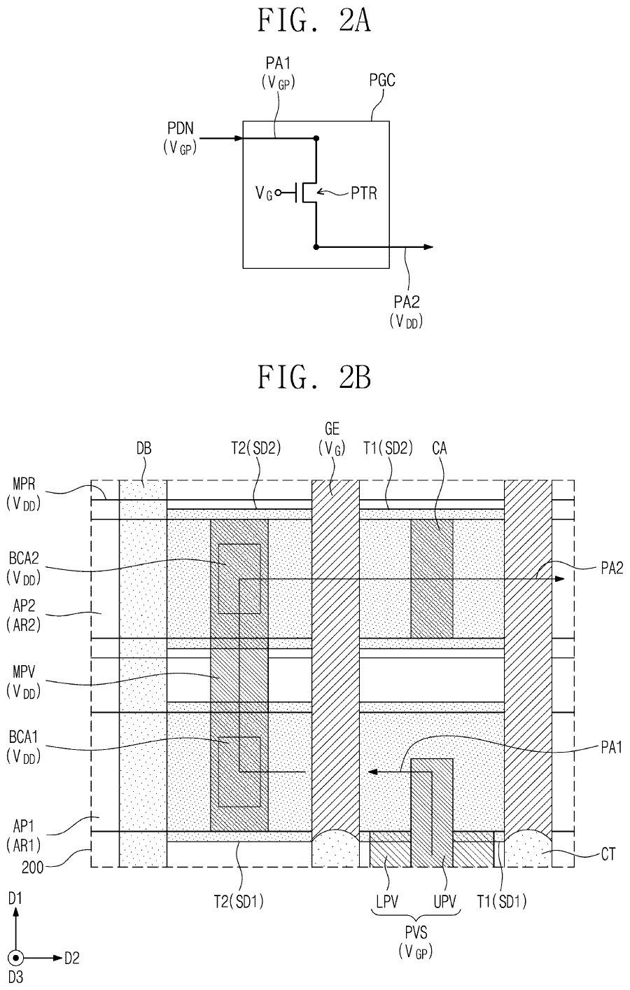

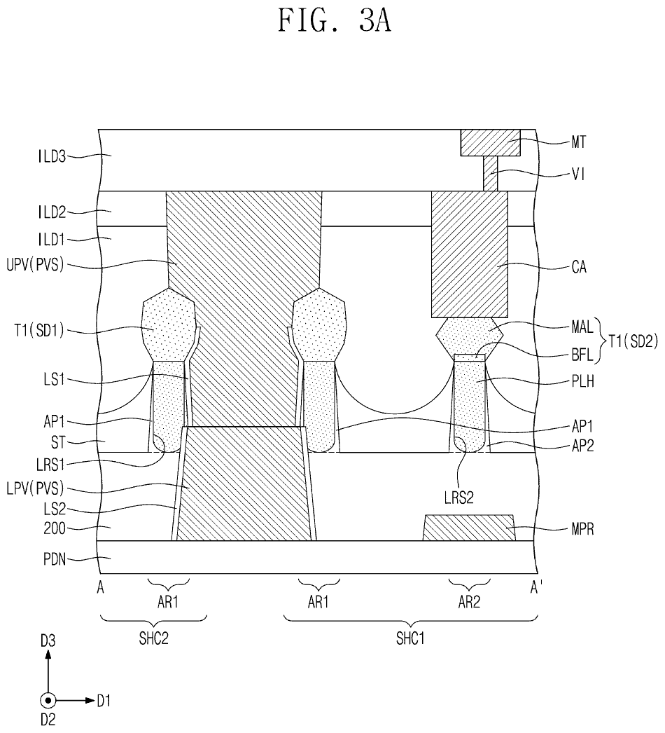

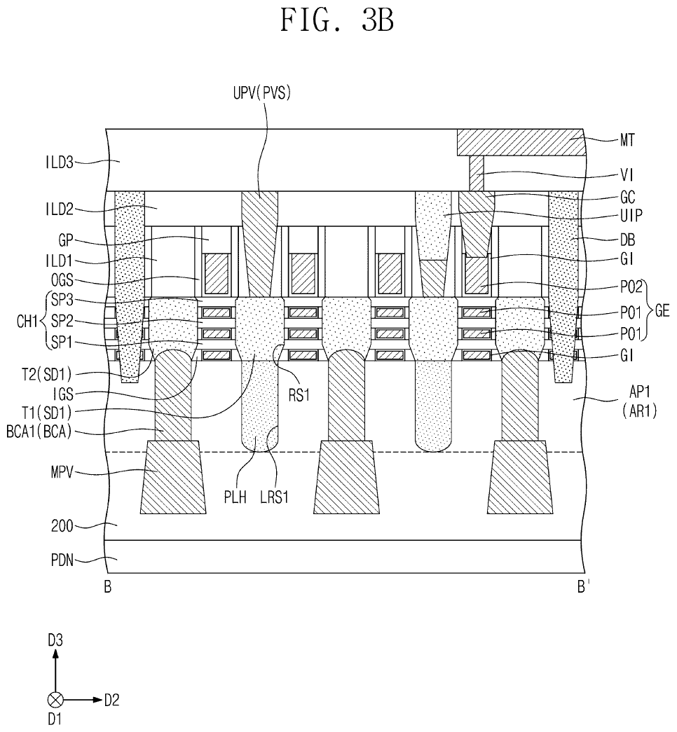

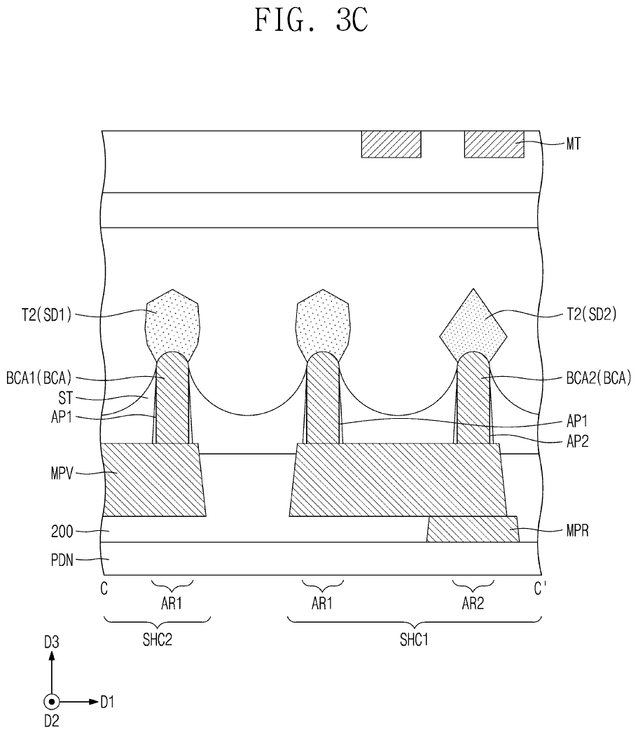

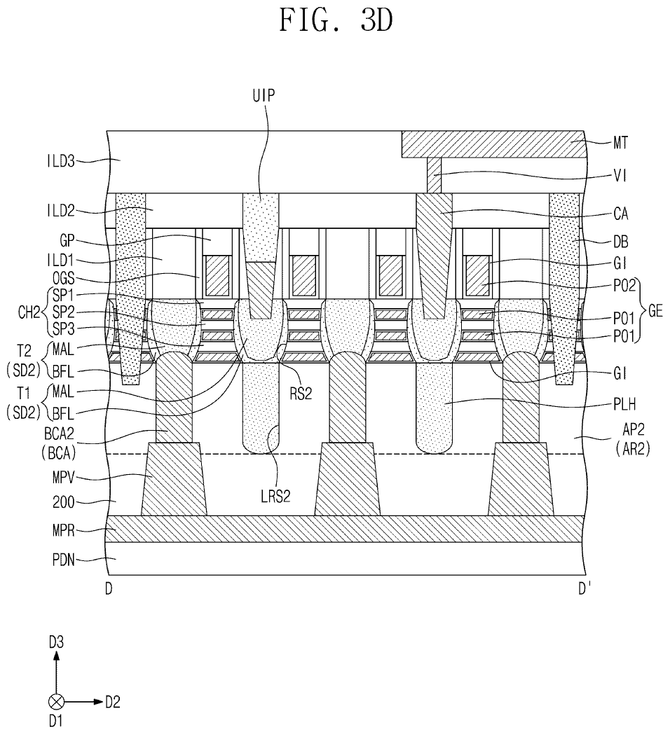

FIG. 1 is a plan view illustrating a semiconductor device according to some implementations of the present disclosure. FIG. 2A is a block diagram illustrating a semiconductor device including a power gating circuit according to some implementations of the present disclosure. FIG. 2B is a partially enlarged view of some configurations of FIG. 1. FIGS. 3A to 3D are cross-sectional views respectively taken along lines A-A′, B-B′, C-C′, and D-D′ of FIG. 1.

Referring to FIGS. 1 and 3A to 3D, a substrate 200 includes a first single height cell SHC1 and a second single height cell SHC2. For example, the substrate 200 may include at least one of silicon (Si), germanium (Ge), silicon-germanium (SiGe), a silicon oxide (SiO2) film, a silicon nitride (SiN) film, or a silicon oxynitride (SiON) film. As used herein, wordings such as “A or B”, “at least one of A and B”, “at least one of A or B”, “A, B, or C”, “at least one of A, B, and C”, and “at least one of A, B, or C” may each include any one of or all possible combinations of items listed together.

The first single height cell SHC1 and the second single height cell SHC2 may each constitute one logic cell. As used herein, the logic cell refers to a logic device (for example, AND, OR, XOR, XNOR, inverter, etc.) that performs a specific function. For example, the logic cell may include transistors that constitute the logic device and lines connecting the transistors to each other. For example, the first single height cell SHC1 and the second single height cell SHC2 may each constitute one power gating cell, e.g., as described below in this disclosure.

The first single height cell SHC1 and the second single height cell SHC2 may be adjacent to each other in a first direction D1. For example, a plurality of single height cells may be adjacent to the first and second single height cells SHC1 and SHC2 in first and second directions D1 and D2. The plurality of single height cells may each constitute one logic cell as described above. The first and second directions D1 and D2 may be each parallel to an upper surface of the substrate 200 and may be perpendicular to each other.

The first and second single height cells SHC1 and SHC2 may each include a first active region AR1 and a second active region AR2 on the substrate 200. The first and second active regions AR1 and AR2 may each extend in the second direction D2 and may be spaced apart from each other in the first direction D1. For example, the first active region AR1 of the first single height cell SHC1 may be adjacent to the first active region AR1 of the second single height cell SHC2 in the first direction D1. For example, the first active region AR1 of the first single height cell SHC1 and the first active region AR1 of the second single height cell SHC2 may be interposed between the second active region AR2 of the first single height cell SHC1 and the second active region AR2 of the second single height cell SHC2. For example, the first active region AR1 may be an NMOS region, and the second active region AR2 may be a PMOS region.

A first active pattern AP1 may be provided in the first active region AR1. A second active pattern AP2 may be provided in the second active region AR2. The first and second active patterns AP1 and AP2 may be each defined by a trench on the substrate 200. The first and second active patterns AP1 and AP2 may be a portion of the substrate 200. For example, the portion of the substrate 200 may protrude in a third direction D3. The third direction D3 may be a direction perpendicular to the upper surface of the substrate 200. For convenience of description, unless otherwise described, the substrate 200 is defined as referring to portions of the substrate 200 excluding the first and second active patterns AP1 and AP2. The first and second active patterns AP1 and AP2 may each extend in the second direction D2.

A device isolation pattern ST may be provided on the substrate 200 and fill the trench. The device isolation pattern ST may at least partially surround the first and second active patterns AP1 and AP2. The device isolation pattern ST may include an insulating material. For example, the device isolation pattern ST may include silicon oxide (SiO₂).

A first channel pattern CH1 (shown, e.g., in FIG. 3B) may be provided on the first active pattern AP1, and a second channel pattern CH2 (shown, e.g., in FIG. 3D) may be provided on the second active pattern AP2. The first channel pattern CH1 may be provided in plurality, and the plurality of first channel patterns CH1 may be spaced apart from each other in the second direction D2. The second channel pattern CH2 may be provided in plurality, and the plurality of second channel patterns CH2 may be spaced apart from each other in the second direction D2. The first and second channel patterns CH1 and CH2 may each include a first semiconductor pattern SP1, a second semiconductor pattern SP2, and a third semiconductor pattern SP3 adjacent to one another or spaced apart from one another in the third direction D3, but are not limited thereto. For example, the first and second channel patterns CH1 and CH2 may each include four or more semiconductor patterns. For example, the first to third semiconductor patterns SP1, SP2, and SP3 may each include crystalline silicon.

First recesses RS1 may be defined between the first channel patterns CH1 adjacent to each other in the second direction D2. Second recesses RS2 may be defined between the second channel patterns CH2 adjacent to each other in the second direction D2.

A first source/drain pattern SD1 may be provided on the first active pattern AP1, and a second source/drain pattern SD2 may be provided on the second active pattern AP2. The first source/drain pattern SD1 may fill the first recess RS1, and the second source/drain pattern SD2 may fill the second recess RS2. The first and second source/drain patterns SD1 and SD2 may be each connected to the first to third semiconductor patterns SP1, SP2, and SP3. As used herein, the meaning of A and B being “connected” may include not only a case in which A and B are electrically connected through a direct contact but also a case in which A and B are indirectly electrically connected through C (for example, a conductive component) therebetween. Here, the component C may be a single component or a plurality of components.

First source/drain patterns SD1 may be impurity regions having a first conductive type (for example, an n-type), and second source/drain patterns SD2 may be impurity regions having a second conductive type (for example, a p-type). For example, a pair of first source/drain patterns SD1 adjacent to each other in the second direction D2 may be connected through the first channel pattern CH1. For example, a pair of second source/drain patterns SD2 adjacent to each other in the second direction D2 may be connected through the second channel pattern CH2.

The first source/drain patterns SD1 may include the same semiconductor element (for example, Si) as the first channel pattern CH1. The second source/drain patterns SD2 may include a semiconductor element (for example, SiGe) having a greater lattice constant than a semiconductor element of the second channel pattern CH2. Accordingly, the pair of second source/drain patterns SD2 may provide a compressive stress to the second channel pattern CH2 therebetween.

The second source/drain pattern SD2 may include a buffer layer BFL covering an inner surface of the second recess RS2 and a main layer MAL filling most of a remaining portion of the second recess RS2. For example, the buffer layer BFL and the main layer MAL may each include silicon-germanium (SiGe). The buffer layer BFL may include germanium (Ge) at a relatively low concentration. The main layer MAL may include germanium (Ge) at a relatively high concentration. As another example, the buffer layer BFL may only include silicon (Si).

The first source/drain pattern SD1 may include a first pattern T1 connected to a through via structure PVS to be described later and a second pattern T2 in contact with a first rear surface conductive contact BCA1 to be described later. The second source/drain pattern SD2 may include a first pattern T1 in contact with an active contact CA to be described later and a second pattern T2 in contact with a second rear surface conductive contact BCA2 to be described later. The first pattern T1 and the second pattern T2 of each of the first and second source/drain patterns SD1 and SD2 may be spaced apart from each other with a gate electrode GE therebetween.

A first lower recess LRS1 may be provided under each of the first patterns T1 of the first source/drain patterns SD1. A second lower recess LRS2 may be provided under each of the second patterns T2 of the second source/drain patterns SD2. A sacrificial contact pattern PLH may fill the inside of each of the first and second lower recesses LRS1 and LRS2. For example, the sacrificial contact pattern PLH may include silicon-germanium (SiGe).

The gate electrode GE may be provided on the first and second channel patterns CH1 and CH2 and cross the first and second channel patterns CH1 and CH2. The gate electrode GE may be provided in plurality. The gate electrodes GE may each extend in the first direction D1, and may be spaced apart from each other in the second direction D2.

The gate electrode GE may include an inner electrode PO1 and an outer electrode PO2. The inner electrode PO1 of the gate electrode GE may be provided between an uppermost semiconductor pattern SP3 among the plurality of semiconductor patterns SP1, SP2, and SP3 and the first and second active patterns AP1 and AP2. The outer electrode PO2 of the gate electrode GE may be provided on the uppermost semiconductor pattern SP3. For example, the inner electrode PO1 of the gate electrode GE may include three electrode portions, but is not limited thereto. For example, the inner electrode PO1 of the gate electrode GE may include four or more electrode portions.

The gate electrode GE may include a first metal pattern, and a second metal pattern on the first metal pattern. The first metal pattern may include a work function metal that controls a threshold voltage of a transistor. For example, the first metal pattern may include at least one of a metal material (for example, Ti, Mo, W, Cu, Al, Ta, Ru, Ir, Co, or the like) or a metal nitride (for example, a nitride of Ti, Mo, W, Cu, Al, Ta, Ru, Ir, Co, or the like). For example, the first metal pattern may further include carbon (C). For example, the first metal pattern may include metal materials having different work functions.

For example, the second metal pattern may include a metal material (for example, Ti, Mo, W, Cu, Al, Ta, Ru, Ir, Co, or the like) having a lower resistance than that of the first metal pattern.

For example, the inner electrode PO1 of the gate electrode GE may include the first metal pattern. For example, the outer electrode PO2 of the gate electrode GE may include the first metal pattern and the second metal pattern.

A cutting pattern CT may be interposed between the gate electrodes GE adjacent to each other in the first direction D1. The cutting pattern CT may be provided in plurality. The cutting patterns CT may be adjacent to each other in the second direction D2. For example, the cutting pattern CT may include an insulating material.

A gate capping pattern GP may be provided on an upper surface of the gate electrode GE. For example, the gate capping pattern GP may include at least one of SiON, SiCN, SiOCN, or SiN.

External gate spacers OGS may be provided on side surfaces of the outer electrode PO2 of the gate electrode GE, and may respectively extend onto side surfaces of the gate capping pattern GP. The external gate spacer OGS may include a single film or a composite film. For example, the external gate spacer OGS may include at least one of SiON, SiCN, SiOCN, or SiN.

A gate insulating pattern GI may be interposed between the gate electrode GE and the first to third semiconductor patterns SP1, SP2, and SP3. The gate insulating pattern GI may cover an upper surface, a lower surface, and both side surfaces of each of the first to third semiconductor patterns SP1, SP2, and SP3. The gate insulating pattern GI may cover an upper surface of the device isolation pattern ST under the gate electrode GE. The gate insulating pattern GI may be interposed between the outer electrode PO2 and the external gate spacer OGS. For example, the gate insulating pattern GI may include at least one of silicon oxide (SiO2), silicon oxynitride (SiON), or a high dielectric material. As used herein, the high dielectric material is defined as a material having a higher dielectric constant than silicon oxide.

An internal gate spacer IGS may be interposed between the second source/drain pattern SD2 and the inner electrode PO1 of the gate electrode GE. For example, the internal gate spacer IGS may include an insulating material.

A first interlayer insulating film ILD1 may be provided on the substrate 200. The first interlayer insulating film ILD1 may cover the external gate spacers OGS and the first and second source/drain patterns SD1 and SD2. An upper surface of the first interlayer insulating film ILD1 may be substantially located at the same level as an upper surface of the gate capping pattern GP and an upper surface of the external gate spacer OGS.

A second interlayer insulating film ILD2 may cover, on the first interlayer insulating film ILD1, the gate capping pattern GP. A third interlayer insulating film ILD3 may be provided on the second interlayer insulating film ILD2. For example, the first to third interlayer insulating films ILD1, ILD2, and ILD3 may include silicon oxide (SiO₂).

The active contact CA may penetrate the first and second interlayer insulating films ILD1 and ILD2 along the third direction D3. The active contact CA may be provided in plurality, and a lower portion of each of the active contacts CA may be buried in an upper portion of the first pattern T1 of the second source/drain pattern SD2. For example, the active contact CA may include at least one of a metal material (for example, Ti, Mo, W, Cu, Al, Ta, Ru, Ir, Co, or the like), a metal nitride (for example, a nitride of Ti, Mo, W, Cu, Al, Ta, Ru, Ir, Co, or the like), or a metal silicide (for example, a silicide of Ti, Mo, W, Cu, Al, Ta, Ru, Ir, or the like). The active contact CA may be connected to the first pattern T1 of the second source/drain pattern SD2.

Gate contacts GC may penetrate the second interlayer insulating film ILD2 and the gate capping pattern GP along the third direction D3. The gate contacts GC may be each buried in an upper portion of the outer electrode PO2 of the gate electrode GE. For example, the gate contacts GC may include at least one of a metal material (for example, Ti, Mo, W, Cu, Al, Ta, Ru, Ir, Co, or the like) or a metal nitride (for example, a nitride of Ti, Mo, W, Cu, Al, Ta, Ru, Ir, Co, or the like).

Isolation patterns DB may be provided on both sides of each of the first and second single height cells SHC1 and SHC2. For example, the isolation patterns DB may include an insulating material. The first and second single height cells SHC1 and SHC2 may be each electrically separated from other cells adjacent in the second direction D2 by the isolation patterns DB.

Metal patterns MT may be provided in the third interlayer insulating film ILD3. Vias VI may be interposed between the metal patterns MT and the active contacts CA, and between the metal patterns MT and the gate contacts GC. The metal patterns MT may be electrically connected to the active contacts CA and the gate contacts GC through the vias VI. For example, although not shown in the drawing, the metal patterns MT and the vias VI may be each provided as a plurality of layers, and each metal pattern MT and each via VI may be alternately stacked. The metal patterns MT and the vias VI may include a metal material (for example, Ti, Mo, W, Cu, Al, Ta, Ru, Ir, Co, or the like).

A power distribution network layer PDN may be provided on a lower surface of the substrate 200. The power distribution network layer PDN may include a plurality of lower wiring connected to the first pattern T1 of the first source/drain pattern SD1 through a through via structure PVS to be described later. For example, the power distribution network layer PDN may include a wiring network for applying a source voltage. For example, the power distribution network layer PDN may include a wiring network for applying a drain voltage.

The through via structure PVS may extend along the third direction D3 on the power distribution network layer PDN. The through via structure PVS may penetrate the substrate 200. For example, the through via structure PVS may be interposed between the first single height cell SHC1 and the second single height cell SHC2. For example, the through via structure PVS may be interposed between the first patterns T1 of the first source/drain pattern SD1 adjacent to each other in the first direction D1.

As shown in FIG. 3A, the through via structure PVS may include an upper power via UPV interposed between the first patterns T1 of the first source/drain pattern SD1 adjacent to each other in the first direction D1 and a lower power via LPV between the power distribution network layer PDN and the upper power via UPV. For example, the upper power via UPV may include at least one of a metal material (for example, Ti, Mo, W, Cu, Al, Ta, Ru, Ir, Co, or the like), a metal nitride (for example, a nitride of Ti, Mo, W, Cu, Al, Ta, Ru, Ir, Co, or the like), or a metal silicide (for example, a silicide of Ti, Mo, W, Cu, Al, Ta, Ru, Ir, or the like). For example, the lower power via LPV may include at least one of a metal material (for example, Ti, Mo, W, Cu, Al, Ta, Ru, Ir, Co, or the like) or a metal nitride (for example, a nitride of Ti, Mo, W, Cu, Al, Ta, Ru, Ir, Co, or the like).

The upper power via UPV may be connected to the power distribution network layer PDN through the lower power via LPV. The upper power via UPV may be connected to the first patterns T1 of the first source/drain pattern SD1. For example, the upper power via UPV may be in contact with the first patterns T1 of the first source/drain pattern SD1. Specifically, for example, a metal silicide in the upper power via UPV and the first patterns T1 of the first source/drain pattern SD1 may be in contact with each other. As a result, a metal material in the upper power via UPV may be connected to the first patterns T1 of the first source/drain pattern SD1 through a metal silicide and a metal nitride in the upper power via UPV. In summary, the through via structure PVS including the upper power via UPV and the lower power via LPV may connect the power distribution network layer PDN and the first patterns T1 of the first source/drain pattern SD1.

A portion of the upper power via UPV may further protrude in the first direction D1 from another portion thereof. The portion of the upper power via UPV may partially cover an upper surface of each of the first patterns T1 of the first source/drain pattern SD1.

The lower power via LPV may be in contact with a lower surface of the upper power via UPV. For example, a width of the lower power via LPV along a horizontal direction of the substrate 200 may become smaller in the third direction D3.

An upper insulating pattern UIP, shown in FIG. 3D, may be provided on each of the upper power via UPV adjacent to the gate contact GC and the active contact CA adjacent to the gate contact GC. For example, the upper insulating pattern UIP may include an insulating material.

A first liner insulating film LS1 may be interposed between the first active pattern AP1 and the upper power via UPV, and between the second active pattern AP2 and the upper power via UPV. The first liner insulating film LS1 may be partially interposed between the upper power via UPV and the first patterns T1 of the first source/drain pattern SD1. For example, the first liner insulating film LS1 may include an insulating material.

A second liner insulating film LS2 may be interposed between the substrate 200 and the lower power via LPV. For example, the second liner insulating film LS2 may include an insulating material.

A rear surface power via MPV, shown in FIG. 3D, may be provided in the substrate 200. The rear surface power via MPV may be buried in the substrate 200. The rear surface power via MPV may extend along the first direction D1. Specifically, the rear surface power via MPV may extend, along the second direction D2, from below the second pattern T2 of the first source/drain pattern SD1 to below the second pattern T2 of the second source/drain pattern SD2. The rear surface power via MPV may vertically overlap each of the second pattern T2 of the first source/drain pattern SD1 and the second pattern T2 of the second source/drain pattern SD2. For example, the rear surface power via MPV may include at least one of a metal material (for example, Ti, Mo, W, Cu, Al, Ta, Ru, Ir, Co, or the like) or a metal nitride (for example, a nitride of Ti, Mo, W, Cu, Al, Ta, Ru, Ir, Co, or the like).

A rear surface conductive contact BCA may be provided on an upper surface of the rear surface power via MPV. For example, the rear surface conductive contact BCA and the rear surface power via MPV may be in contact with each other with a step therebetween. The rear surface conductive contact BCA may include the first rear surface conductive contact BCA1 between the second pattern T2 of the first source/drain pattern SD1 and the rear surface power via MPV and the second rear surface conductive contact BCA2 between the second pattern T2 of the second source/drain pattern SD2 and the rear surface power via MPV. The first and second rear surface conductive contacts BCA1 and BCA2 may each include at least one of a metal material (for example, Ti, Mo, W, Cu, Al, Ta, Ru, Ir, Co, or the like) or a metal nitride (for example, a nitride of Ti, Mo, W, Cu, Al, Ta, Ru, Ir, Co, or the like).

The first rear surface conductive contact BCA1 may be connected to each of the second pattern T2 of the first source/drain pattern SD1 and the rear surface power via MPV. For example, the first rear surface conductive contact BCA1 may be in contact with each of a lower surface of the second pattern T2 of the first source/drain pattern SD1 and an upper surface of the rear surface power via MPV. The rear surface power via MPV may be connected to the second pattern T2 of the first source/drain pattern SD1 through the first rear surface conductive contact BCA1.

The second rear surface conductive contact BCA2 may be connected to each of the second pattern T2 of the second source/drain pattern SD2 and the rear surface power via MPV. For example, the second rear surface conductive contact BCA2 may be in contact with each of a lower surface of the second pattern T2 of the second source/drain pattern SD2 and an upper surface of the rear surface power via MPV. The rear surface power via MPV may be connected to the second pattern T2 of the second source/drain pattern SD2 through the second rear surface conductive contact BCA2.

A rear surface power rail MPR may be provided in the substrate 200. The rear surface power rail MPR may be buried in the substrate 200. The rear surface power rail MPR may be provided below the second source/drain pattern SD2 and vertically overlap the second source/drain pattern SD2. For example, the rear surface power rail MPR may not vertically overlap the first source/drain pattern SD1. The rear surface power rail MPR may extend along the second direction D2 below the second source/drain pattern SD2. The rear surface power rail MPR may be connected, below the second source/drain pattern SD2, to the rear surface power via MPV. For example, an upper surface of the rear surface power rail MPR may be in contact with a lower surface of the rear surface power via MPV. For example, the rear surface power rail MPR may include at least one of a metal material (for example, Ti, Mo, W, Cu, Al, Ta, Ru, Ir, Co, or the like) or a metal nitride (for example, a nitride of Ti, Mo, W, Cu, Al, Ta, Ru, Ir, Co, or the like).

Hereinafter, with reference to FIGS. 2A, 2B, and 3A to 3D, how a voltage applied from the power distribution network layer PDN is transmitted to other logic cells adjacent to the first and second single height cells SHC1 and SHC2 through various components will be described, based on the components' connections to one another.

Firstly, referring to FIGS. 1 and 2A, the first single height cell SHC1 and the second single height cell SHC2 may each constitute one power gating cell including a power gating circuit PGC. For example, the power gating circuit PGC may be provided on the first active region AR1 of each of the first single height cell SHC1 and the second single height cell SHC2. The power gating circuit PGC may provide power to the second active region AR2 of the first single height cell SHC1, the second active region AR2 of the second single height cell SHC2, and other logic cells adjacent to the first and second single height cells SHC1 and SHC2.

The power gating circuit PGC may be connected to the power distribution network layer PDN which provides a global power voltage V_{GP}. The power gating circuit PGC may include a first connection line PA1, a power gating transistor PTR, and a second connection line PA2. The global power voltage V_{GP} applied from the power distribution network layer PDN may be transmitted to the power gating transistor PTR through the first connection line PA1.

A gate voltage V_{G} may be applied to the power gating transistor PTR. The gate voltage V_{G} may correspond to a voltage for turning on the power gating transistor PTR. For example, when a voltage equal to or greater than the gate voltage V_{G} is applied to the power gating transistor PTR, the power gating transistor PTR may be turned on, and thus the first connection line PA1 and the second connection line PA2 may be connected to each other. As a result, a power voltage V_{DD} may be transmitted to the second connection line PA2. The power voltage V_{DD} may be transmitted to the logic cells adjacent to the first and second single height cells SHC1 and SHC2 through the second connection line PA2.

As another example, when a voltage smaller than the gate voltage V_{G} is applied to the power gating transistor PTR, the power gating transistor PTR may be turned off, and thus the first connection line PA1 and the second connection line PA2 may not be connected to each other. As a result, the power voltage V_{DD} may not be transmitted to the second connection line PA2, and the second connection line PA2 may be floated.

The power gating circuit PGC in the power gating cell may selectively transmit the power voltage V_{DD} to the second connection line PA2, or selectively float the second connection line PA2. Accordingly, the power gating cell may selectively transmit the power voltage V_{DD} to only a logic cell that requires power supply. As a result, power use of the semiconductor device may be reduced, thereby reducing power consumption of the semiconductor device.

Referring to FIGS. 2B and 3A to 3D, the global power voltage V_{GP} may be applied from the power distribution network layer PDN. As described above, the power distribution network layer PDN may be connected to the through via structure PVS. Accordingly, the global power voltage V_{GP} may be transmitted to the through via structure PVS. As described above, the through via structure PVS may be connected to the first pattern T1 of the first source/drain pattern SD1. Accordingly, the first pattern T1 of the first source/drain pattern SD1 may be connected to the power distribution network layer PDN through the through via structure PVS. The through via structure PVS and the first pattern T1 of the first source/drain pattern SD1 may constitute the first connection line PA1 described with reference to FIG. 2A.

The first pattern T1 and the second pattern T2 of the first source/drain pattern SD1, the first channel pattern CH1 therebetween, and the gate electrode GE traversing the first channel pattern CH1 may constitute the power gating transistor PTR described with reference to FIG. 2A.

For example, when a voltage equal to or greater than the gate voltage V_{G} is applied to the gate electrode GE, the power gating transistor PTR (see FIG. 2A) may be turned on, and thus the first pattern T1 of the first source/drain pattern SD1 may be electrically connected to the second pattern T2 of the first source/drain pattern SD1 through the first channel pattern CH1. As a result, the global power voltage V_{GP} transmitted through the first connection line PA1 may be transmitted to the second pattern T2 of the first source/drain pattern SD1. A voltage received by the second pattern T2 of the first source/drain pattern SD1 is defined as the power voltage V_{DD}.

As described above, the rear surface power via MPV may be connected to the second pattern T2 of the first source/drain pattern SD1 through the first rear surface conductive contact BCA1. Accordingly, the power voltage V_{DD} may be transmitted to the rear surface power via MPV through the first rear surface conductive contact BCA1.

As described above, the rear surface power via MPV may be connected to the second pattern T2 of the second source/drain pattern SD2 through the second rear surface conductive contact BCA2. Accordingly, the power voltage V_{DD} may be transmitted to the second pattern T2 of the second source/drain pattern SD2 through the second rear surface conductive contact BCA2.

As described above, the rear surface power via MPV may be connected to the rear surface power rail MPR. Accordingly, the power voltage V_{DD} may be transmitted to the rear surface power rail MPR.

The second pattern T2 of the first source/drain pattern SD1, the first rear surface conductive contact BCA1, the rear surface power via MPV, and the rear surface power rail MPR may constitute the second connection line PA2 described with reference to FIG. 2A.

As described above and shown in FIG. 3D, the rear surface power rail MPR may extend along the second direction D2 below the second source/drain pattern SD2. Accordingly, the power voltage V_{DD} may be transmitted to other logic cells adjacent to the first single height cell SHC1 in the second direction D2 through the rear surface power rail MPR in the first single height cell SHC1. In addition, the power voltage V_{DD} may be transmitted to other logic cells adjacent to the second single height cell SHC2 in the second direction D2 through the rear surface power rail MPR in the second single height cell SHC2.

The power distribution network layer PDN may be connected to the first connection line PA1 (e.g., the through via structure PVS and the first pattern T1 of the first source/drain pattern SD1). Accordingly, the global power voltage V_{GP} applied from the power distribution network layer PDN may be transmitted to the first connection line PA1. In addition, when the power gating transistor is turned on, the first connection line PA1 may be connected to the second connection line PA2 (for example, the second pattern T2 of the first source/drain pattern SD1, the first rear surface conductive contact BCA1, the rear surface power via MPV, and the rear surface power rail MPR). Accordingly, the power voltage V_{DD} may be transmitted to the second connection line PA2, and the power voltage V_{DD} may be transmitted to other logic cells through the second connection line PA2. A portion of the first connection line PA1 and a portion of the second connection line PA2 may be buried in the substrate 200, and thus a degree of freedom in arrangement of various components for driving the power gating cell may be improved. As a result, the semiconductor device may be easily designed.

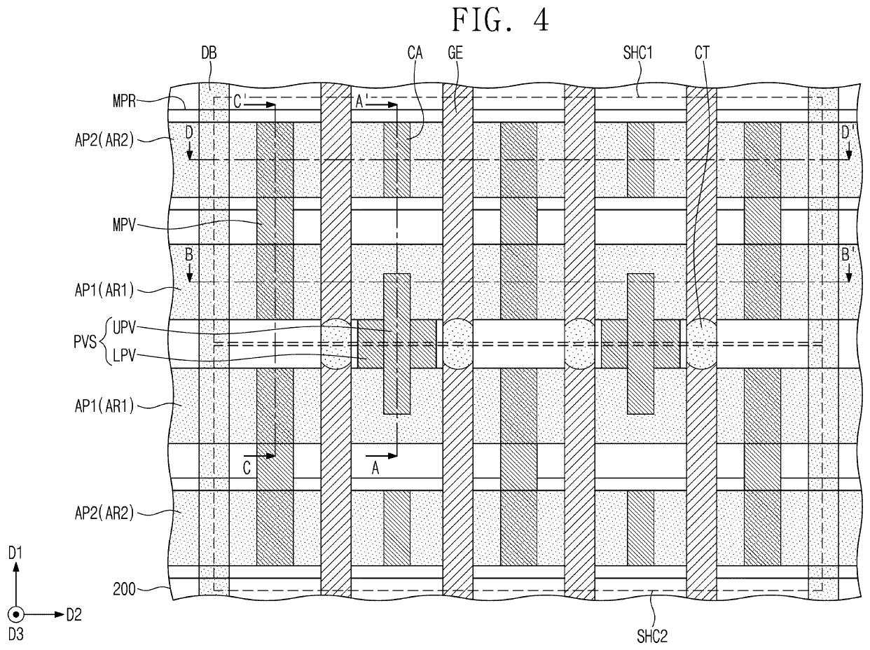

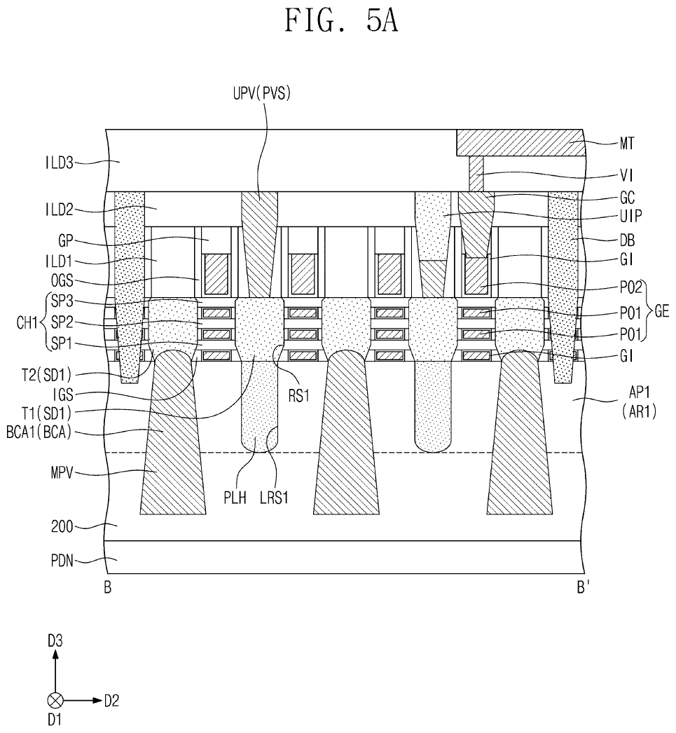

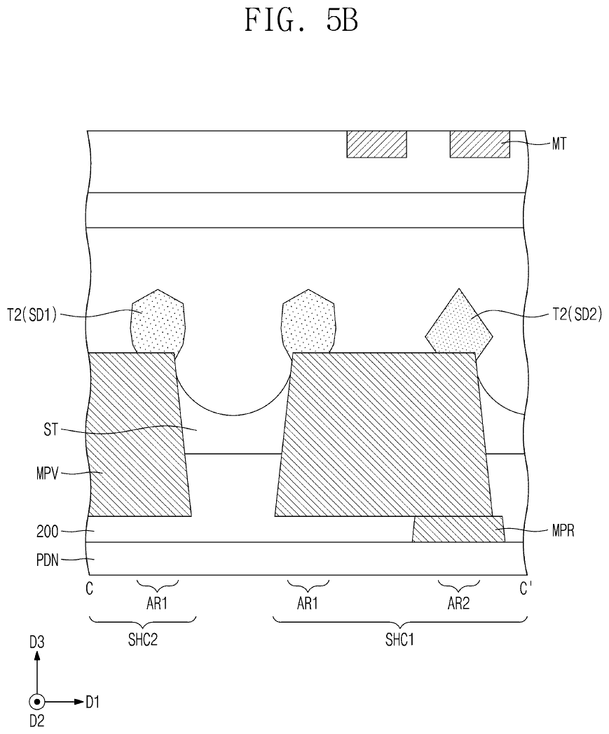

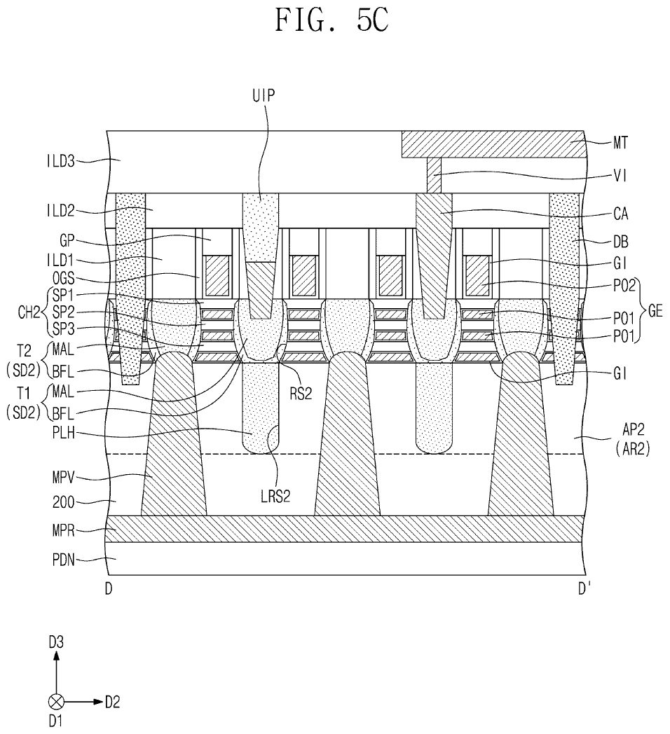

Hereinafter, a semiconductor device according to some implementations of the present disclosure will be described with reference to FIGS. 4 to 5C. For simplification of description, description overlapping with the above description will not be provided, and a difference from the above description will be mainly described; the description provided with respect to FIGS. 1 to 3D applies equally to FIGS. 4 to 5C, except where indicated otherwise or suggested otherwise by context.

FIG. 4 is a plan view illustrating an example of a semiconductor device. FIGS. 5A to 5C are cross-sectional views respectively taken along lines B-B′, C-C′, and D-D′ of FIG. 4.

Referring to FIGS. 4 and 5A to 5C, unlike what is described with reference to FIGS. 1 and 3A to 3D, a rear surface conductive contact BCA may be omitted.

A rear surface power via MPV may penetrate a first active pattern AP1 and may be in contact with a second pattern T2 of a first source/drain pattern SD1. Accordingly, the rear surface power via MPV may be connected to a second pattern T2 of the first source/drain pattern SD1 without a first rear surface conductive contact BCA1.

The rear surface power via MPV may penetrate a second active pattern AP2 and may be in contact with a second pattern T2 of a second source/drain pattern SD2. Accordingly, the rear surface power via MPV may be connected to the second pattern T2 of the second source/drain pattern SD2 without a second rear surface conductive contact BCA2.

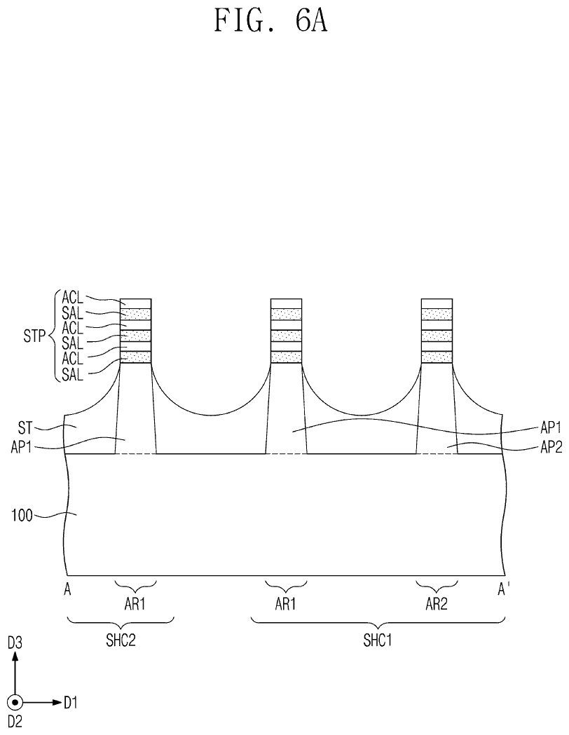

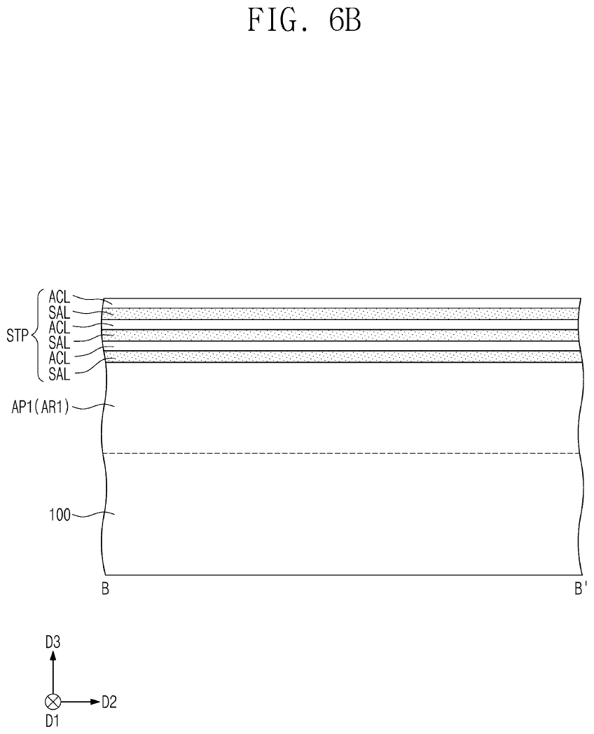

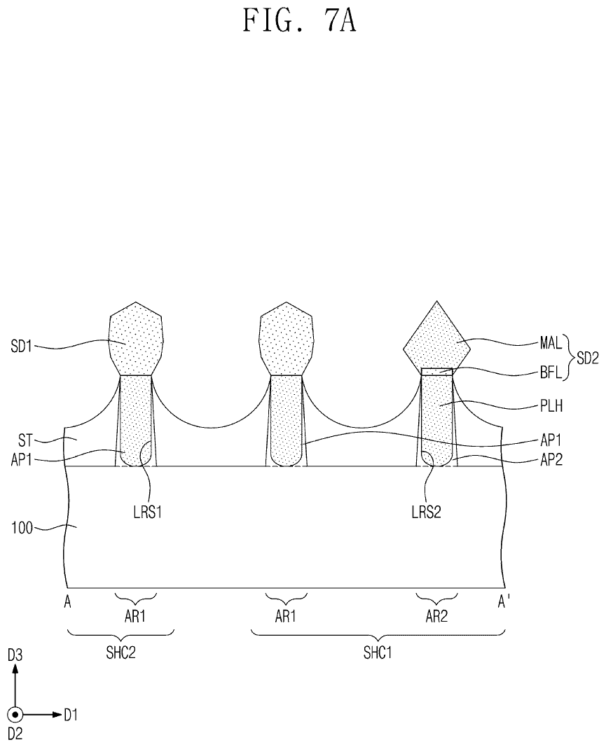

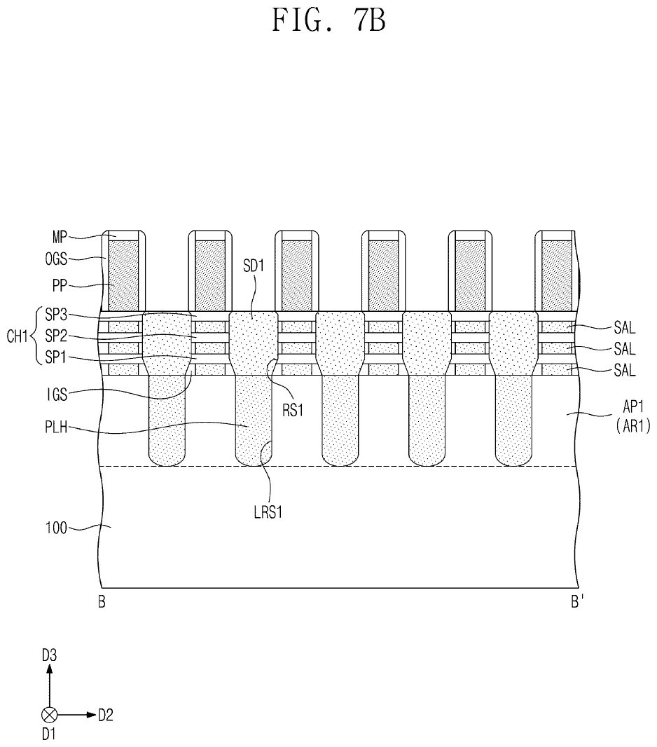

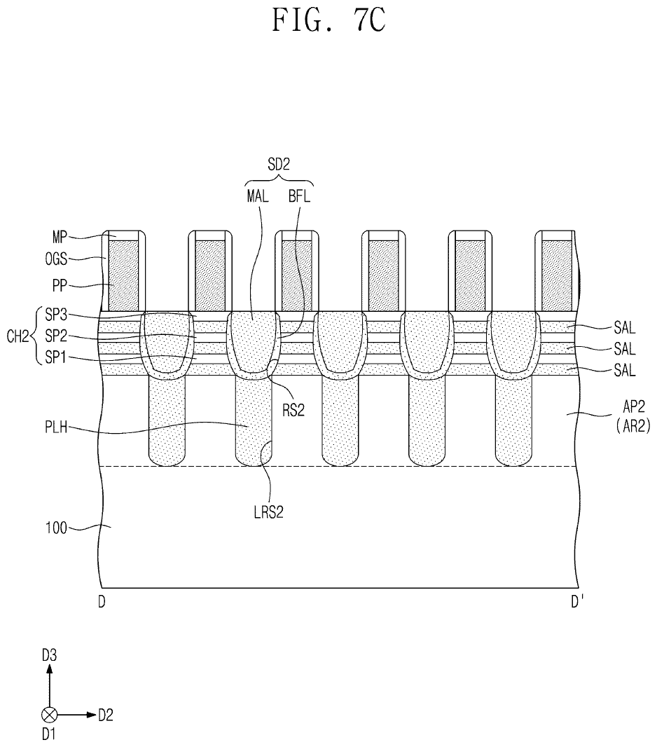

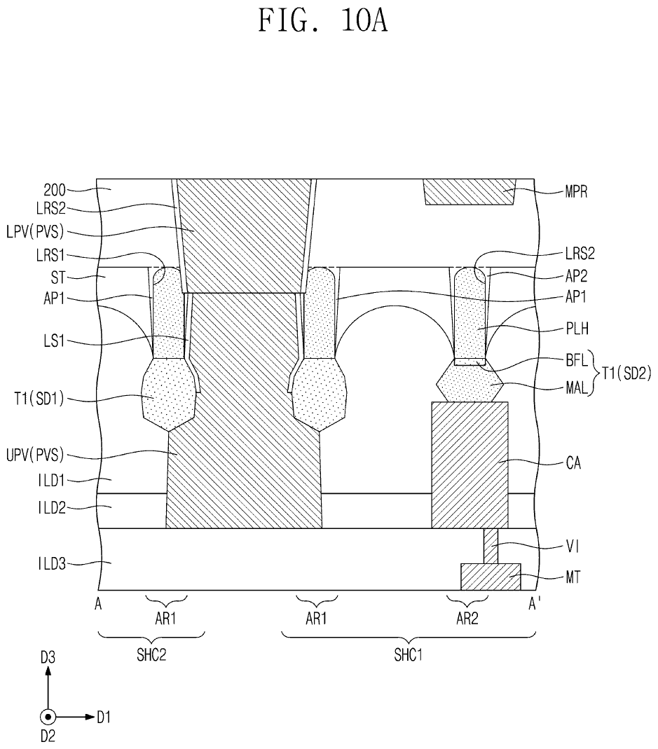

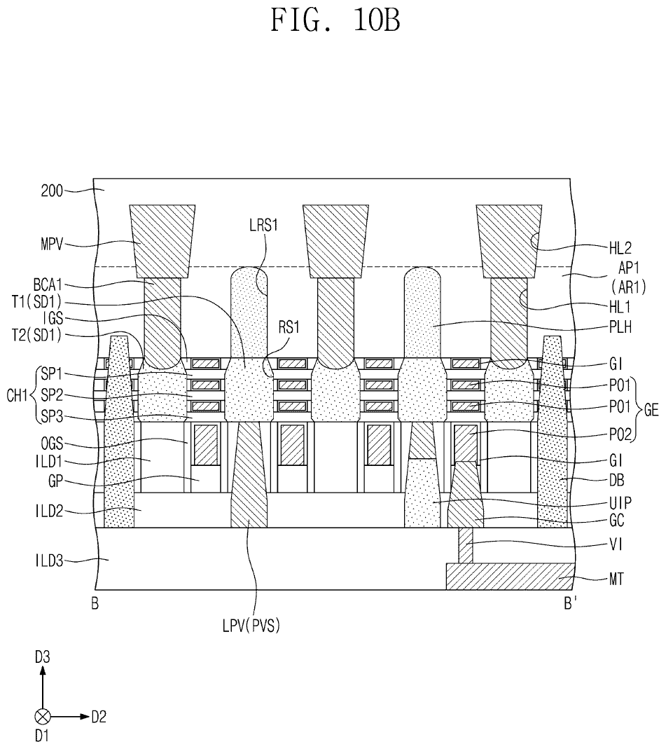

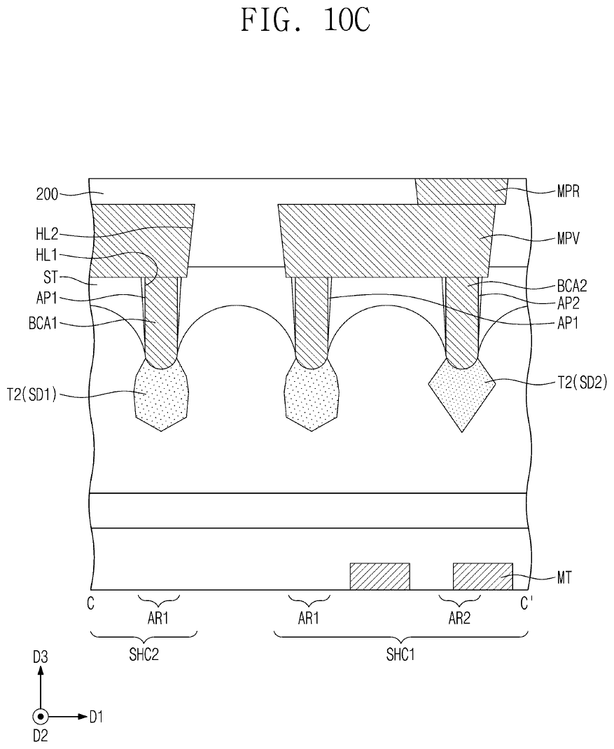

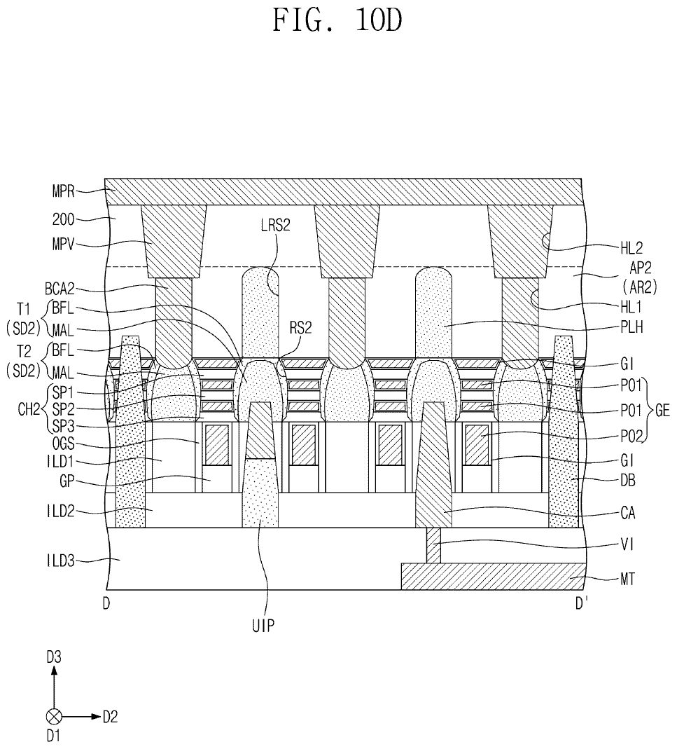

FIGS. 6A to 10D are diagrams illustrating a method for manufacturing a semiconductor device according some implementations of the present disclosure. More specifically, FIGS. 6A, 7A, 9A, and 10A are cross-sectional views taken along line A-A′ of FIG. 1. FIGS. 6B, 7B, 8, 9B, and 10B are cross-sectional views taken along line B-B′ of FIG. 1. FIG. 10C is a cross-sectional view taken along line C-C′ of FIG. 1. FIGS. 7C and 10D are cross-sectional views taken along line D-D′ of FIG. 1.

Referring to FIGS. 1, 6A, and 6B, a semiconductor substrate 100 including a first active region AR1 and a second active region AR2 may be provided. For example, the semiconductor substrate 100 may be a semiconductor substrate including a semiconductor material, such as a single-crystalline silicon substrate, a silicon-germanium substrate, and a SOI substrate. Stack patterns STP may be formed on the first active region AR1 and the second active region AR2. For example, forming the stack patterns STP may include alternately stacking semiconductor layers ACL and sacrificial layers SAL on the semiconductor substrate 100, forming mask patterns (not shown) extending in a second direction D2, and performing a patterning process using the mask patterns as etching masks. During the patterning process, a portion of the semiconductor substrate 100 may be removed together, and trenches defining a first active pattern AP1 and a second active pattern AP2 may be formed. Device isolation patterns ST may be formed to fill the trenches.

The sacrificial layers SAL may include a material capable of having etching selectivity with the semiconductor layers ACL. Accordingly, when performing a process of removing the sacrificial layers SAL to be described later, even if the sacrificial layers SAL are removed, the semiconductor layers ACL may not be removed or may be slightly removed. For example, the semiconductor layers ACL may include one among silicon (Si), germanium (Ge), and silicon-germanium (SiGe), and the sacrificial layers SAL may include one, which is different from the semiconductor layers ACL, among silicon (Si), germanium (Ge), and silicon-germanium (SiGe).

Referring to FIGS. 1 and 7A to 7C, sacrificial patterns PP may be formed to each extend along a first direction D1 on the semiconductor substrate 100. The sacrificial patterns PP may be formed to cover upper surfaces of the device isolation patterns ST and side surfaces and upper surfaces of the stack patterns STP. For example, forming the sacrificial patterns PP may include forming a sacrificial film on a front surface of the semiconductor substrate 100, forming hard mask patterns MP on the sacrificial film, and forming the sacrificial patterns PP by partially removing the sacrificial film using the hard mask patterns MP as etching masks. For example, the sacrificial pattern PP may include polysilicon. Thereafter, external gate spacers OGS may be formed on side surfaces of the sacrificial patterns PP.

First recesses RS1 may be formed in the stack pattern STP on the first active pattern AP1. Second recesses RS2 may be formed in the stack pattern STP on the second active pattern AP2. For example, the first and second recesses RS1 and RS2 may be formed by partially removing the stack pattern STP using the hard mask patterns MP as etching masks.

The semiconductor layers ACL on the first active pattern AP1 may be divided into first channel patterns CH1 spaced apart from each other in the second direction D2 by the first recesses RS1. The semiconductor layers ACL on the second active pattern AP2 may be divided into second channel patterns CH2 spaced apart from each other in the second direction D2 by the second recesses RS2. The first and second channel patterns CH1 and CH2 may each include first to third semiconductor patterns SP1, SP2, and SP3.

The sacrificial layer SAL exposed by the second recess RS2 may be partially replaced with an insulating material, and thus inner spacers not shown may be formed on both side surfaces of the sacrificial layer SAL.

A first lower recess LRS1 may be formed under the first recess RS1. A second lower recess LRS2 may be formed under the second recess RS2. A sacrificial contact pattern PLH may be formed to fill the inside of the lower recesses LRS1 and LRS2 through a SEG process using the semiconductor substrate 100 as a seed.

First source/drain patterns SD1 may be formed in the first recesses RS1. The first source/drain patterns SD1 may be formed through a selective epitaxial growth (SEG) process using the sacrificial contact pattern PLH and the first to third semiconductor patterns SP1, SP2, and SP3 on the first active region AR1 as seeds.

For example, during a process of forming the first source/drain pattern SD1, impurities (for example, phosphor, arsenic, or antimony) allowing the first source/drain pattern SD1 to have an n-type may be in-situ injected into the first source/drain pattern SD1. As another example, after the first source/drain pattern SD1 is formed, the impurities may be injected into the first source/drain pattern SD1.

Second source/drain patterns SD2 may be formed in the second recesses RS2. The second source/drain patterns SD2 may be formed through a SEG process using the sacrificial contact pattern PLH and the first to third semiconductor patterns SP1, SP2, and SP3 on the second active region AR2 as seeds.

For example, during a process of forming the second source/drain pattern SD2, impurities (for example, boron, gallium, or indium) allowing the second source/drain pattern SD2 to have a p-type may be in-situ injected into the second source/drain pattern SD2. As another example, after the second source/drain pattern SD2 is formed, the impurities may be injected into the second source/drain pattern SD2.

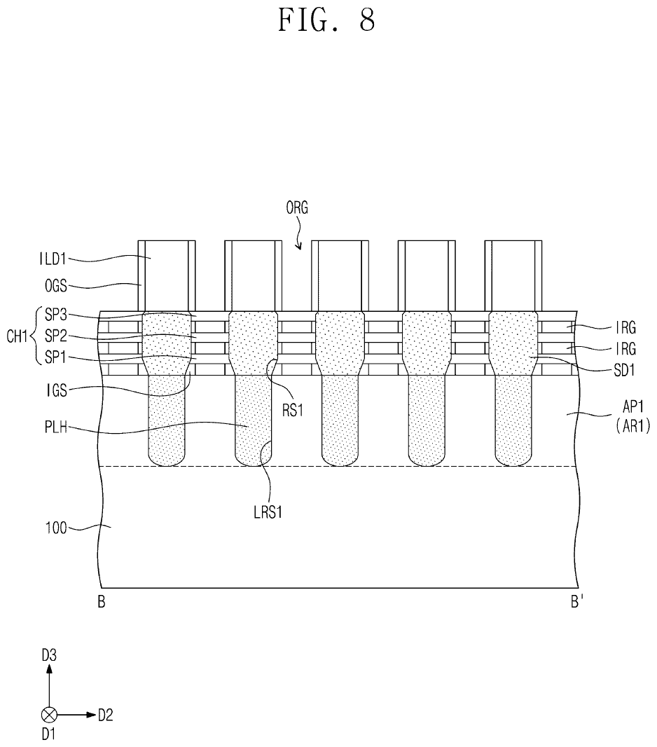

Referring to FIGS. 1 and 8, a first interlayer insulating film ILD1 may be formed to cover the first source/drain pattern SD1, the second source/drain pattern SD2 (see FIG. 7C), the hard mask patterns MP, and external gate spacers OGS. Thereafter, the first interlayer insulating film ILD1 on upper surfaces of the sacrificial patterns PP may be removed. During the removing process, the hard mask patterns MP may be removed together, and the sacrificial patterns PP may be exposed.

Thereafter, the exposed sacrificial patterns PP may be removed, and an outer region ORG may be formed in a region in which the sacrificial patterns PP are removed. The first channel pattern CH1, the second channel pattern CH2 (see FIG. 7C), and the sacrificial layers SAL may be exposed to the outside by the outer region ORG.

Thereafter, the exposed sacrificial layers SAL may be selectively removed. Here, the first to third semiconductor patterns SP1, SP2, and SP3 may not be removed or may be slightly removed due to high etching selectivity of the sacrificial layers SAL.

Inner regions IRG may be formed in a region in which the sacrificial layers SAL are removed. Specifically, the inner regions IRG may be formed between the first to third semiconductor patterns SP1, SP2, and SP3.

A gate insulating pattern GI may be formed in each of the inner regions IRG and the outer region ORG. The gate insulating pattern GI may be formed to surround each of the first to third semiconductor patterns SP1, SP2, and SP3.

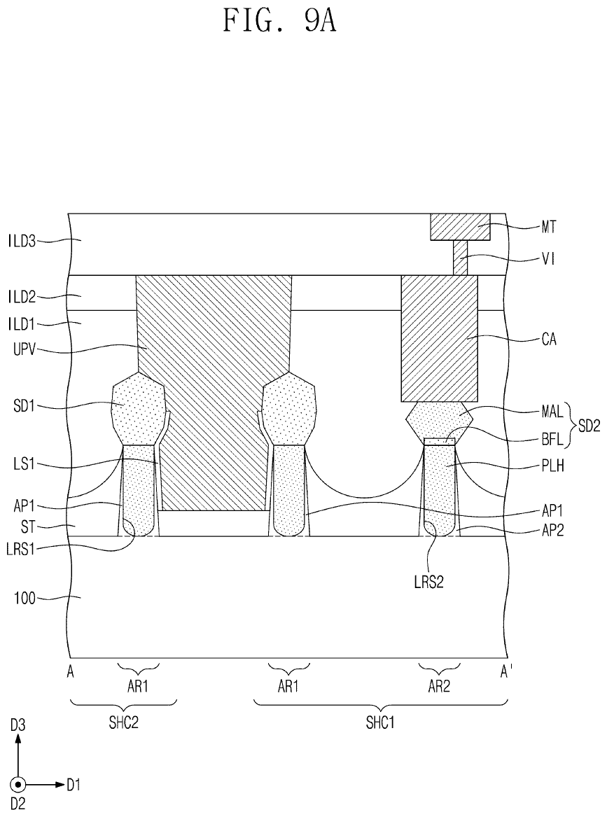

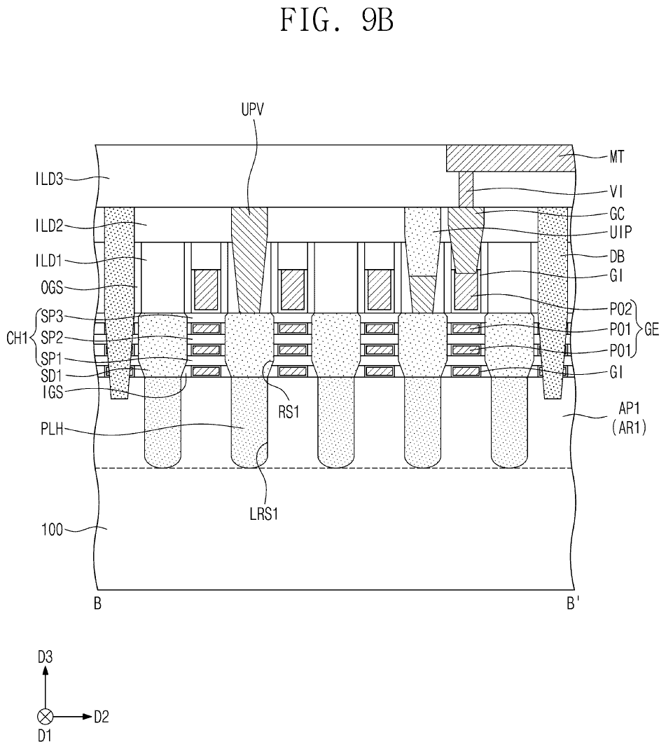

Referring to FIGS. 1, 9A, and 9B, a gate electrode GE may be formed on the gate insulating pattern GI. The gate electrode GE may include an inner electrode PO1 which is formed in each of the inner regions IRG and an outer electrode PO2 which is formed in the outer region ORG. Thereafter, a gate capping pattern GP may be formed on the outer electrode PO2 of the gate electrode GE.

A second interlayer insulating film ILD2 may be formed on the first interlayer insulating film ILD1 and the gate capping pattern GP. Active contacts CA may be formed to penetrate the first and second interlayer insulating films ILD1 and ILD2 and partially connected to the second source/drain patterns SD2.

A first liner insulating film LS1 may be formed to partially cover the first active pattern AP1 and the first source/drain pattern SD1. An upper power via UPV may be formed between the first source/drain patterns SD1. For example, forming the first liner insulating film LS1 and the upper power via UPV may include partially exposing the first source/drain pattern SD1 by partially removing each of the device isolation pattern ST, the first interlayer insulating film ILD1, and the second interlayer insulating film ILD2, forming the first liner insulating film LS1 covering the first source/drain pattern SD1, partially removing the first liner insulating film LS1 to partially expose the first source/drain pattern SD1, and filling a region in which each of the device isolation pattern ST, the first interlayer insulating film ILD1, and the second interlayer insulating film ILD2 are partially removed with the upper power via UPV.

An upper portion of each of a portion of the active contacts CA and a portion of upper power vias UPV may be removed, and an upper insulating pattern UIP may be formed to fill the removed region.

Gate contacts GC may be formed to penetrate the second interlayer insulating film ILD2 and the gate capping pattern GP and connected to gate electrodes GE.

A third interlayer insulating film ILD3 may be formed on the second interlayer insulating film ILD2. Metal patterns MT and vias VI may be formed in the third interlayer insulating film ILD3.

Referring to FIGS. 1 and 10A to 10D, after a back end of line (BEOL) process is completed, the semiconductor substrate 100 described with reference to FIGS. 6A and 6B may be turned upside down. Accordingly, a lower surface of the semiconductor substrate 100 (see FIGS. 6A and 6B) may be exposed. Since the semiconductor substrate 100 (see FIGS. 6A and 6B) is turned upside down, in describing with reference to FIGS. 10A to 10D below, the terms “upper surface” and “upper portion” may respectively mean “lower surface” and “lower portion” with respect to the completely manufactured semiconductor device described with reference to FIGS. 3A to 3D, and the terms “lower surface” and “lower portion” may respectively mean “upper surface” and “upper portion” with respect to the completely manufactured semiconductor device described with reference to FIGS. 3A to 3D.

A thickness of the semiconductor substrate 100 (see FIGS. 6A and 6B) may be reduced by performing a planarization process on the exposed surface of the semiconductor substrate 100 (see FIGS. 6A and 6B). For example, the semiconductor substrate 100 (see FIGS. 6A and 6B) may be entirely removed or only partially removed through the planarization process.

Insulating films including an insulating material may be formed to fill a removed region of the semiconductor substrate 100 (see FIGS. 6A and 6B). The insulating films and a remaining portion of the semiconductor substrate 100 (see FIGS. 6A and 6B) may constitute a substrate 200.

A hole on the upper power via UPV may be formed by performing a patterning process on the substrate 200. A second liner insulating film LS2 covering the hole may be formed. Thereafter, a lower power via LPV filling a remaining portion of the hole may be formed.

The sacrificial contact pattern PLH on a second pattern T2 of each of the first and second source/drain patterns SD1 and SD2 may be removed. A first hole HL1 may be formed on the second pattern T2 of each of the first and second source/drain patterns SD1 and SD2 through the removing process. Thereafter, first rear surface conductive contacts BCA1 filling first holes HL1 on second patterns T2 of the first source/drain pattern SD1 may be formed. Second rear surface conductive contacts BCA2 filling first holes HL1 on second patterns T2 of the second source/drain pattern SD2 may be formed.

A second hole HL2 may be formed on the first and second rear surface conductive contacts BCA1 and BCA2. The second hole HL2 may be formed to extend from an upper surface of the first rear surface conductive contact BCA1 to an upper surface of the second rear surface conductive contact BCA2. The upper surface of the first rear surface conductive contact BCA1 and the upper surface of the second rear surface conductive contact BCA2 may be exposed by the second hole HL2.

A rear surface power via MPV may be formed to fill the inside of the second hole HL2. As another example, a process of forming the first hole HL1 and a process of forming the first and second rear surface conductive contacts BCA1 and BCA2 may be skipped, and the second hole HL2 may be formed to expose an upper surface of the second pattern T2 of the first source/drain pattern SD1 and an upper surface of the second pattern T2 of the second source/drain pattern SD2. Here, the rear surface power via MPV may be formed to fill the inside of the second hole HL2, and as a result, the rear surface power via MPV described with reference to FIGS. 4 and 5A to 5C may be formed.

A rear surface power rail MPR may be formed on an upper surface of the rear surface power via MPV.

Referring back to FIGS. 1 and 3A to 3D, a power distribution network layer PDN may be formed on a lower surface of the substrate 200.

As a result, a semiconductor device may include a power gating cell. Accordingly, the power gating cell may selectively transmit a power voltage only to a logic cell that requires power supply. As a result, power use of the semiconductor device may be minimized, and thus power consumption of the semiconductor device may be reduced.

Moreover, some lines for driving the power gating cell may be buried in a substrate. Accordingly, a degree of freedom in arrangement of various components for driving the power gating cell may be improved. As a result, the semiconductor device may be easily designed.

In addition, the power gating cells may be driven through a lower surface of a substrate, providing improved design flexibility.

In addition, a power voltage may be provided to a PMOS device (e.g., in the second active region AR2) through an NMOS device (e.g., in the second active region AR1), as shown in FIG. 2B and 3C. The power voltage may be provided through the MPV. The power can then be routed to other devices in a same cell/active region as the PMOS device, e.g., along direction D2, e.g., using the MPR.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although various examples have been described with reference to the accompanying drawings, concepts described herein can be carried out in other specific forms without departing from the scope of this disclosure. Therefore, the above examples should be considered illustrative.

What is claimed is:

1. A semiconductor device comprising:
a power distribution network layer on a lower surface of a substrate;
a gate electrode on the substrate;
a first source/drain pattern and a second source/drain pattern on the substrate, the first and second source/drain patterns each including a first pattern and a second pattern spaced apart from each other with the gate electrode therebetween;
a through via structure extending in the substrate along a direction perpendicular to an upper surface of the substrate, the through via structure connecting the power distribution network layer and the first pattern of the first source/drain pattern; and
a rear surface power via extending from a first position that is below the second pattern of the first source/drain pattern to a second position that is below the second pattern of the second source/drain pattern.

2. The semiconductor device of claim 1, wherein the rear surface power via is connected to each of the second pattern of the first source/drain pattern and the second pattern of the second source/drain pattern.

3. The semiconductor device of claim 1, wherein the second pattern of the first source/drain pattern and the second pattern of the second source/drain pattern each vertically overlap the rear surface power via.

4. The semiconductor device of claim 1, wherein the through via structure is connected to the rear surface power via through the first and second patterns of the first source/drain pattern.

5. The semiconductor device of claim 1, comprising a rear surface power rail that contacts a lower surface of the rear surface power via below the second pattern of the second source/drain pattern.

6. The semiconductor device of claim 5, wherein the rear surface power rail extends, below the second source/drain pattern, along a direction parallel to the upper surface of the substrate.

7. The semiconductor device of claim 5, wherein the rear surface power rail vertically overlaps the second source/drain pattern.

8. The semiconductor device of claim 5, wherein the through via structure is connected to the rear surface power rail through the first pattern and the second pattern of the first source/drain pattern and through the rear surface power via.

9. The semiconductor device of claim 5, wherein the rear surface power via extends along a direction perpendicular to a direction along which the rear surface power rail extends.

10. The semiconductor device of claim 1, further comprising:
a first rear surface conductive contact between the rear surface power via and the second pattern of the first source/drain pattern; and
a second rear surface conductive contact between the rear surface power via and the second pattern of the second source/drain pattern.

11. The semiconductor device of claim 1, wherein the rear surface power via is in contact with each of the second pattern of the first source/drain pattern and the second pattern of the second source/drain pattern.

12. The semiconductor device of claim 1, further comprising a first channel pattern between the first pattern and the second pattern of the first source/drain pattern,
wherein the first pattern and the second pattern of the first source/drain pattern are connected through the first channel pattern.

13. A semiconductor device comprising:
a power distribution network layer on a lower surface of a substrate;
a gate electrode on the substrate;
a first source/drain pattern and a second source/drain pattern on the substrate, the first and second source/drain patterns each including a first pattern and a second pattern spaced apart from each other with the gate electrode therebetween;
a through via structure extending in the substrate and along a direction perpendicular to an upper surface of the substrate, the through via structure connecting the power distribution network layer and the first pattern of the first source/drain pattern;
a rear surface power rail extending in a first direction parallel to the upper surface of the substrate below the second source/drain pattern; and
a rear surface power via extending from a first position that is below the second pattern of the first source/drain pattern to an upper surface of the rear surface power rail.

14. The semiconductor device of claim 13, wherein the rear surface power via is connected to each of the second pattern of the first source/drain pattern and the second pattern of the second source/drain pattern.

15. The semiconductor device of claim 13, wherein the through via structure is connected to the rear surface power rail through the first pattern and the second pattern of the first source/drain pattern and through the rear surface power via.

16. The semiconductor device of claim 13, wherein the rear surface power via extends from the first position to a second position that is below the second pattern of the second source/drain pattern.

17. The semiconductor device of claim 13, wherein the rear surface power via extends along a second direction perpendicular to the first direction along which the rear surface power rail extends.

18. The semiconductor device of claim 13, comprising a first channel pattern between the first pattern and the second pattern of the first source/drain pattern,
wherein the first pattern and the second pattern of the first source/drain pattern are connected through the first channel pattern.

19. A semiconductor device comprising:
a power distribution network layer on a lower surface of a substrate;
a gate electrode on the substrate;
a first source/drain pattern and a second source/drain pattern on the substrate, the first and second source/drain patterns each including a first pattern and a second pattern spaced apart from each other with the gate electrode therebetween;
a first channel pattern between the first pattern and the second pattern of the first source/drain pattern;
a through via structure extending in the substrate and along a direction perpendicular to an upper surface of the substrate, the through via structure connecting the power distribution network layer and the first pattern of the first source/drain pattern;
an active contact on the first pattern of the second source/drain pattern;
a rear surface power rail extending in a direction parallel to the upper surface of the substrate below the second source/drain pattern; and
a rear surface power via extending from a first position that is below the second pattern of the first source/drain pattern to an upper surface of the rear surface power rail.

20. The semiconductor device of claim 19, wherein the through via structure is connected to the rear surface power rail through the first pattern of the first source/drain pattern, the first channel pattern, the second pattern of the first source/drain pattern, and the rear surface power via.
